(19) United States
(12) Patent Application Publication
(10) Pub. No.: US 2011/0102704 A1
(43) Pub. Date: May 5, 2011

(54) WHITE LED FOR LIQUID CRYSTAL DISPLAY BACKLIGHTS

(75) Inventors: William Dunn, Alpharetta, GA (US); Harry Presley, Alpharetta, GA (US)

(73) Assignee: MANUFACTURING RESOURCES INTERNATIONAL, INC., Alpharetta, GA (US)

(21) Appl. No.: 12/768,296

(22) Filed: Apr. 27, 2010

Related U.S. Application Data
(60) Provisional application No. 61/173,184, filed on Apr. 27, 2009.

(51) Int. Cl. G02F 1/1335; H01L 33/40; H01L 33/44; F21V 9/00

(52) U.S. Cl. 349/61; 257/98; 438/29; 362/231; 257/E33.063

(57) ABSTRACT

A light emitting diode (LED), method for optimizing an LED having characteristics which are tailored for a liquid crystal color filter set, and a liquid crystal display (LCD) using the LED are disclosed. The spectral response of the LED is optimized to provide the preferred optical properties when its light is transmitted through the color filter set and liquid crystal stack. Embodiments provide a diode chip which intrinsically emits light with wavelengths primarily within the blue visible spectrum (‘blue chip’). Surrounding the chip would be a first layer of phosphor that emits light with wavelengths primarily within the yellow-green region of the visible spectrum via phosphorescence with the blue light which is emitted from the diode chip (‘yellow-green phosphor’). There would also preferably be a second layer of phosphor that emits light with wavelengths primarily within the red region of the visible spectrum via phosphorescence with the blue light which is emitted from the diode chip (‘red phosphor’).

### CROSS-REFERENCE TO RELATED APPLICATIONS

This application is a non-provisional patent application and claims priority to co-pending U.S. Application No. 61/173,184 filed on Apr. 27, 2009 and herein incorporated by reference in its entirety.

### TECHNICAL FIELD

This invention generally relates to white LEDs which provide optimal optical properties when used through the color filters for liquid crystal displays (LCDs).

### BACKGROUND OF THE ART

LCDs contain several layers which work in combination to create a viewable image. A backlight is used to generate the rays of light that pass through what is commonly referred to as the LCD stack, which typically contains several layers that perform either basic or enhanced functions. The most fundamental layer within the LCD stack is the liquid crystal material, which may be actively configured in response to an applied voltage in order to pass or block a certain amount of light which is originating from the backlight. The layer of liquid crystal material is divided into many small regions which are typically referred to as pixels. For full-color displays these pixels are further divided into independently-controllable regions of red, green and blue subpixels, where the red subpixel has a red color filter, blue subpixel has a blue color filter, and green subpixel has a green color filter. These three colors are typically called the primary colors. For example, when the applied voltage to one of the red subpixels is activated then the associated red portion of the backlight spectrum that is incident on this subpixel is allowed to pass and therefore become part of the image that is viewed on the display.

The light which is passing through each subpixel originates as “white” (or broadband) light from the backlight, although in general this light is far from being uniform across the visible spectrum. The subpixel color filters allow each subpixel to transmit a certain amount of each color (red, green or blue). When viewed from a distance, the three subpixels appear as one composite pixel and by electrically controlling the amount of light which passes for each subpixel color the composite pixel can produce a very wide range of different colors via the effective mixing of light from the red, green, and blue subpixels.

Currently, the common illumination source for LCD backlight assemblies is fluorescent tubes, but the industry is moving toward light emitting diodes (LEDs). Environmental concerns (for example, mercury in florescent tubes), small space requirements, low energy consumption, and long lifetime are some of the reasons that the LCD industry is beginning the widespread usage of LEDs for backlights. As noted above, backlights typically produce light over a broad spectrum that may appear mostly white in color. When using LEDs, this is typically accomplished in one of two ways: 1) individual clusters of red, green and blue LEDs (herein ‘ROB backlights’); or 2) white-emitting LEDs (herein ‘white LED backlights’).

Each LED has its own set of optical properties which may define it. These properties may include color temperature, efficacy, and spectral response. When these LEDs are purchased from suppliers, their optical properties are sometimes well defined and controlled. However, in LCD applications the light from these LEDs will pass through the color filters in the liquid crystal layer, thus altering its optical properties. With this in mind, RGB backlights sometimes provide some benefit since the levels of each color can be increased/decreased in order to create the desired “shade of white” for the overall backlight.

However, RGB backlights suffer several disadvantages compared to white LED backlights. RGB backlights have higher manufacturing costs and require more expensive and complicated control systems. Further, while RGB backlights may produce a larger color gamut, the image quality is more likely to degrade if the color gamut is extended more than necessary because it causes the display to render incorrect colors. Thus, there exists a need for white LED backlights which provide optimal optical properties once the light has passed through a set of color filters.

### SUMMARY OF THE EXEMPLARY EMBODIMENTS

Exemplary embodiments include a white LED which is optimized for the spectral transmission of LCD color filters and maximizes the resulting optical properties which are displayed by the LCD. Embodiments provide a diode chip which intrinsically emits light with wavelengths primarily within the blue visible spectrum (blue chip'). One type of diode chip would be a chip with an InGaN-based active layer. Surrounding the chip would be a first layer of phosphor that emits light with wavelengths primarily within the yellow-green region of the visible spectrum via phosphorescence with the blue light which is emitted from the diode chip (‘yellow-green phosphor’). There may also be a second layer of phosphor that emits light with wavelengths primarily within the red region of the visible spectrum via phosphorescence with the blue light which is emitted from the diode chip (‘red phosphor’). Upon consideration of the spectral transmission of the LCD color filters, the peak wave lengths and relative magnitudes for the blue chip, yellow-green phosphor, and red phosphor may be placed so that there is minimal out-of-band light leakage between the color filters. The resulting colors from the LCD may simultaneously provide a high level of color saturation, display a relatively large percentage of the National Television System Committee (NTSC) color gamut, and also display an ideal white point correlated color temperature (CCT).

The foregoing and other features and advantages of the present invention will be apparent from the following more detailed description of the particular embodiments, as illustrated in the accompanying drawings.

### BRIEF DESCRIPTION OF THE DRAWINGS

A better understanding of an exemplary embodiment will be obtained from a reading of the following detailed description and the accompanying drawings wherein identical reference characters refer to identical parts and in which:

FIG. 1 is a graphical representation of the spectral transmission of typical blue, green, and red LCD color filters.

FIG. 2 is a graphical representation of the spectral transmission of the color filters along with the spectral response of an exemplary LED.

FIG. 3 is a graphical representation of a simulated resulting color gamut of an LCD display using the typical color filters with an exemplary LED.

### DETAILED DESCRIPTION

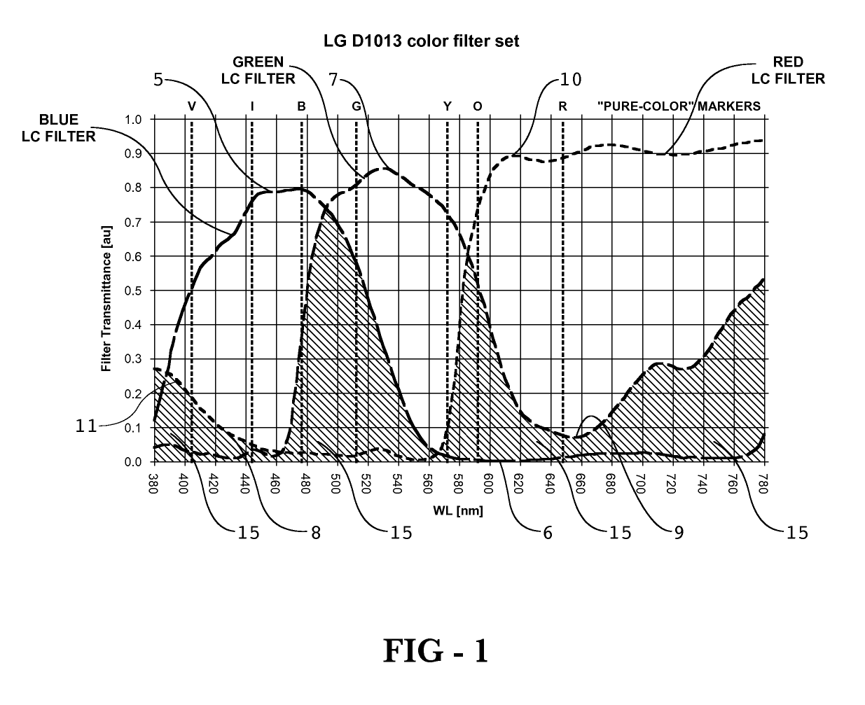

FIG. 1 provides the spectral transmission of typical blue, green, and red LCD color filters. The specific data used for this explanation is taken from the color filters available from LG Electronics of Englewood Cliffs, N.J., part number LGD-D1013. (www.lge.com) It should be noted that although these specific color filters are used within this specification, the techniques taught herein can be applied to any type of LCD color filters to obtain the best optical performance of the LCD.

As is familiar in the art, the x-axis of the figure provides the wavelength (here in nanometers) and the y-axis provides the relative response of each filter. The blue filter has a peak 5 and a node 6. The green filter has peak 7 and nodes 8 and 9. The red filter has a peak 10 in the red visible spectrum and a smaller peak 11 near the violet portion of the visible spectrum. Otherwise, the red filter has a very low spectral transmission between 440 and 570 nm. Several overlap areas 15 are shown where the filter responses overlap one another. This can be very detrimental to the color saturation observed from the LCD display. The exemplary embodiments are designed to achieve the best possible color saturation, NTSC percentage, and white point correlated color temperature (CCT) with color filters that contain these types of overlap areas and spectral transmission characteristics. Again, while discussed specifically with respect to this color filter, by using the designs and methods herein one could design other LED arrangements which would optimize color filters having different spectral transmission curves.

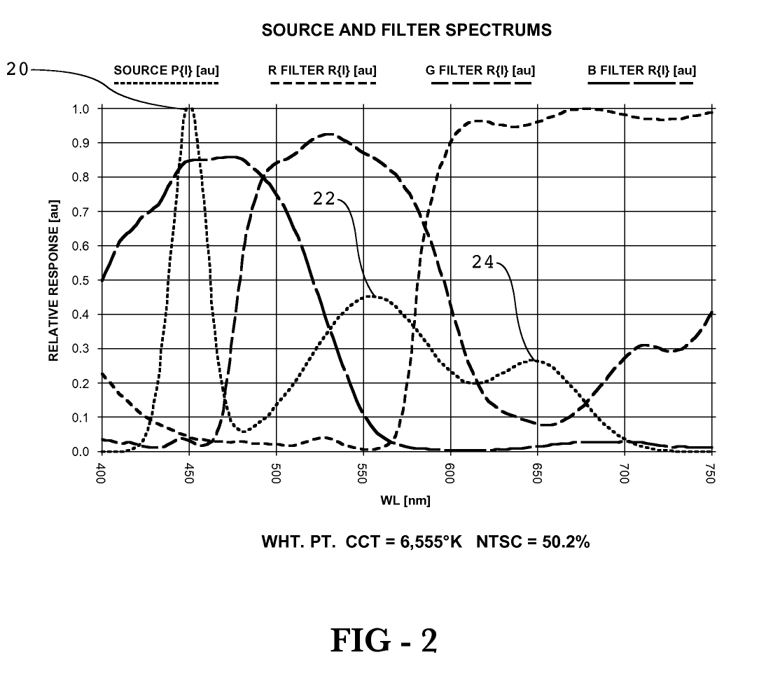

FIG. 2 provides the spectral transmission of the color filters from FIG. 1 along with the spectral response of an exemplary LED (shown as ‘source’ in the figure). Three distinct peaks can be seen in the response curve for the LED. The blue peak 20 corresponds with the blue chip which is pumping the phosphors. The yellow-green peak 22 corresponds with the yellow-green phosphor. The red peak 24 corresponds with the red phosphor. As can be readily observed, the peaks of the LED not only correspond with the associated peaks of the color filter but also correspond with the low points (or nodes) of the color filters which do not correspond with the associated LED peak. Thus, at the wavelength where the blue peak 20 occurs, the relative transmission of the red and green filters is very low. Further, at the wavelength where the yellow-green peak 22 occurs, the relative transmission of the red and blue filters is very low. Finally, at the wavelength where the red peak 24 occurs, the relative transmission of the green and blue filters is very low. The location of the peaks 20, 22, and 24 minimize the light leakage through the other color filters, thus maximizing the color saturation. The relative magnitudes of the peaks 20, 22, and 24 also allow for a near perfect white point CCT.

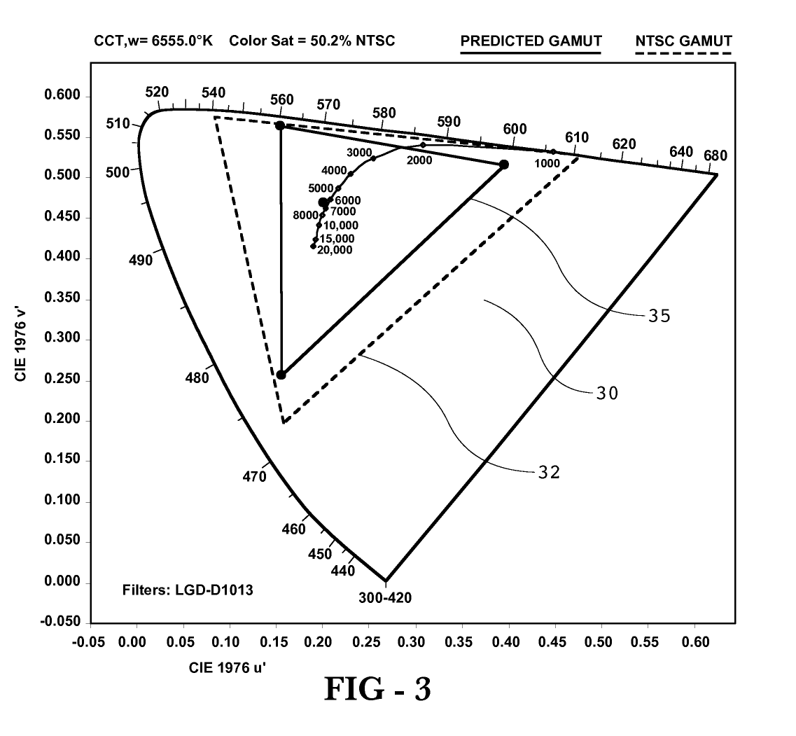

FIG. 3 shows simulation data for a resulting LCD display which would contain the color filters and LEDs as described in FIGS. 1 and 2. As is well known in the art, this plot shows the CIE color space 30 which is known as a representation of the full gamut of colors which can be seen by the human eye. Within the CIE color space 30 is the NTSC color gamut 32 which is known as the color space for current broadcast television (in the United States and some other countries). Within the NTSC color gamut 32 is the resulting color gamut 35 of an LCD resulting from the color filters and LEDs as shown in FIGS. 1 and 2.

One way to measure the color gamut of an LCD television is the percentage of the NTSC color gamut that the LCD can reproduce. It is a delicate balance between achieving both a large NTSC percentage as well as an ideal white point CCT (the precise color temperature of the ‘white’ which is displayed by the LCD).

Exemplary LEDs which perform the techniques taught herein can achieve a near ‘perfect’ white from the resulting LCD. Here, the simulation data shows that a white point of 6,555 degrees K may be achieved. For LCD displays, a white point CCT near 6,500 degrees K is commonly regarded as ‘perfect.’ These LEDs can also achieve a color saturation of 50.2% NTSC which is regarded as ‘good.’

The data shown in FIG. 3 is simulation data based on real data from the color filters and blue LEDs having yellow-green phosphor. Simulation software such as this can be purchased from Breault Research Organization, Inc. www.breault.com. One version of the software is available from Breault as ASAP. The data shown herein was generated by proprietary software but has been verified by confirming with ASAP models.

Again, as mentioned above, RGB LED backlights can typically produce a wider color gamut than white LED backlights. However, these systems must be carefully monitored and can easily drift from desired performance if not controlled accurately. Further, obtaining a near perfect 6,500 CCT can be very difficult and/or expensive to maintain. Also, if a single red, green, or blue LED were to fail, the display in that area would have a different color when compared to the rest of the display.

By using the techniques taught herein, a simplified white LED backlight can be used to create an LCD display with high color saturation and a near perfect white point CCT. The display can be produced faster and with less expensive components than a similar RGB backlit LCD.

Having shown and described a preferred embodiment of the invention, those skilled in the art will realize that many variations and modifications may be made to affect the described invention and still be within the scope of the claimed invention. Additionally, many of the elements indicated above may be altered or replaced by different elements which will provide the same result and fall within the spirit of the claimed invention. It is the intention, therefore, to limit the invention only as indicated by the scope of the claims.

We claim:

1. A light-emitting diode (LED) comprising:
a diode chip which intrinsically emits light within the blue wavelength region;
an overlying layer of phosphor that emits light in the yellow-green wavelength region via phosphorescence with the blue light which is emitted from the diode chip; and
an overlying layer of phosphor that emits light in the red wavelength region via phosphorescence with the blue light which is emitted from the diode chip.

2. The LED of claim 1 wherein:
the spectral response of the LED contains a first peak between approximately 440 and 460 nanometers.

3. The LED of claim 2 wherein:
the spectral response of the LED contains a second peak between approximately 535 and 565 nanometers.

4. The LED of claim 3 wherein:
the spectral response of the LED contains a third peak between approximately 635 and 660 nanometers.

5. The LED of claim 4 wherein:
the spectral response of the LED contains a first node between approximately 470 and 490 nanometers.

6. The LED of claim 5 wherein:
the spectral response of the LED contains a second node between approximately 600 and 625 nanometers.

7. A method for optimizing the backlight LEDs for a given LCD stack and color filter set having red, blue, and green filters which have a relative spectral transmission varying between 0.0 and 1.0 in the visible spectrum, the method comprising the steps of:
selecting an intrinsically blue-emitting LED chip such that the peak of the resulting LED's relative spectral response in the blue visible spectrum corresponds with a wavelength where the relative spectral transmission of both the red and green color filters are less than approximately 0.15;
applying a yellow/green-emitting phosphor to the blue-emitting chip, where the yellow/green-emitting phosphor is selected such that the peak of the resulting LED's relative spectral response in the yellow-green visible spectrum corresponds with a wavelength where the relative spectral transmission of both the red and blue color filters are less than approximately 0.2; and
applying a red-emitting phosphor to the blue-emitting chip, where the red-emitting phosphor is selected such that the peak of the resulting LED's relative spectral response in the red visible spectrum corresponds with a wavelength where the relative spectral transmission of the green and blue color filters are less than approximately 0.15.

8. The method of claim 7 further comprising the steps of:
Illuminating the LCD stack and color filter set using a plurality of LEDs resulting from the method of claim 7.

9. The method of claim 8 wherein:
the resulting white light which is emitted through the LCD stack and color filters has a color temperature between approximately 6400° K and 6600° K.

10. The method of claim 8 wherein:
the resulting colored light which is emitted through the LCD stack and color filters has a color saturation between approximately 49.0% and 55% NTSC.

11. A liquid crystal display comprising:
a color filter set having red, blue, and green filters which have a relative spectral transmission varying between approximately 0.0 and 1.0 in the visible spectrum;
a layer of liquid crystal material placed behind the color filter set;
a backlight placed behind the liquid crystal material, the backlight comprising a plurality of LEDs with each LED comprising:
a diode chip which intrinsically emits light within the blue wavelength region;
an overlying layer of phosphor that emits light in the yellow-green wavelength region via phosphorescence with the blue light which is emitted from the diode chip; and
an overlying layer of phosphor that emits light in the red wavelength region via phosphorescence with the blue light which is emitted from the diode chip.

12. The liquid crystal display of claim 11 wherein:
the spectral response of each backlight LED contains a first peak between approximately 440 and 460 nanometers.

13. The liquid crystal display of claim 12 wherein:
the spectral response of each backlight LED contains a second peak between approximately 535 and 565 nanometers.

14. The liquid crystal display of claim 13 wherein:
the spectral response of each backlight LED contains a third peak between approximately 635 and 660 nanometers.

15. The liquid crystal display of claim 14 wherein:
the spectral response of each backlight LED contains a first node between approximately 470 and 490 nanometers.

16. The liquid crystal display of claim 15 wherein:
the spectral response of each backlight LED contains a second node between approximately 600 and 625 nanometers.

17. The liquid crystal display of claim 11 wherein:
the diode chip provides a peak of the resulting LED's relative spectral response in the blue visible spectrum which corresponds with a wavelength where the relative spectral transmission of both the red and green color filters are less than approximately 0.15.

18. The liquid crystal display of claim 17 wherein:
the yellow/green-emitting phosphor provides a peak of the resulting LED's relative spectral response in the yellow-green visible spectrum which corresponds with a wavelength where the relative spectral transmission of both the red and blue color filters are less than approximately 0.2.

19. The liquid crystal display of claim 18 wherein:
the red-emitting phosphor provides a peak of the resulting LED's relative spectral response in the red visible spectrum which corresponds with a wavelength where the relative spectral transmission of both the green and blue color filters are less than approximately 0.15.
